(19) United States
(12) Patent Application Publication
(10) Pub. No.: US 2016/0191059 A1
(43) Pub. Date: Jun. 30, 2016

(54) CROSS-COUPLED LEVEL SHIFTER WITH TRANSITION TRACKING CIRCUITS

(71) Applicant: SanDisk Technologies Inc., Plano, TX (US)

(72) Inventors: Shiv Harit Mathur, Bangalore (IN); Anand Sharma, Bangalore (IN); Ramakrishnan Subramanian, Bangalore (IN)

(21) Appl. No.: 14/667,082

(22) Filed: Mar. 24, 2015

(30) Foreign Application Priority Data
Dec. 29, 2014 (IN) 4181/MUM/2014

(51) Int. Cl. H03K 19/0185

(52) U.S. Cl. CPC H03K 19/018521

(57) ABSTRACT

A transition tracking circuit may be configured to receive a first input signal and a second input signal from a level shifter. The transition tracking circuit may be configured to track earlier falling transitions of the first and second signals to generate an output signal.

### CROSS-REFERENCE TO RELATED APPLICATIONS

This application claims priority to Indian Patent Application No. 4181/MUM/2014, filed Dec. 29, 2014. The contents of Indian Patent Application No. 4181/MUM/2014 are incorporated by reference in their entirety.

### BACKGROUND

Level shifters are electronic circuits that convert input signals having high and low voltage levels in a first voltage domain to output signals having high and low voltage levels in a second voltage domain. While some level shifters may have high gain characteristics, which may be beneficial for low-to-high type level shifters, such level shifter may have drawbacks due to inherent self-loading characteristics, such as low conversion speeds and mismatch between rise and fall times, which may lead to variations in delay and duty cycle. These drawbacks may have degrade downstream performance, which may use one or more of the output signals in the second voltage domain generated by the level shifter. As such, subsequent modification of the signals generated by the level shifter in order to mitigate the impact that self-loading may have on the duty cycle and delay, maintain the same frequency of operation, or otherwise improve performance may be desirable.

### SUMMARY

In a first aspect, a transition tracking circuit may include a node at which an output signal is generated, and pull-up and pull-down circuitry coupled to the node. The pull-up and pull-down circuitry may be configured to receive a first input signal and a second input signal, wherein during each of a plurality of time periods, the first input signal and the second input signal each perform a first transition and a second transition, the first transition performed by the first input signal occurring earlier than the first transition performed by the second input signal and the second transition performed by the second input signal occurring earlier than the second transition performed by the first input signal. Addition, the pull-up and pull-down circuitry may be configured to begin pulling up an amplitude of the output signal generated at the node from a low level in response to the earlier first transition performed by the first input signal, and begin pulling down the amplitude of the output signal generated at the node from a high level in response to the earlier second transition performed by the second input signal.

In a second aspect, a method of generating an output signal may include receiving, with a transition tracking circuit, a pair of complimentary input signals comprising a first signal and a second signal. During a first time period portion of each of a plurality of time periods, the first input signal may perform a first falling transition earlier than the second input signal performs a first rising transition. During a second time period portion of each of the plurality of time periods, the second input signal may perform a second falling transition earlier than first input signal performs a second rising transition. The method may further include generating, at a node of the transition tracking circuit, the output signal having an amplitude that transitions between a high level and a low level, where generating the output signal at the node may include initiating the transitions of the amplitude of the output signal between the high level and the low level in response to the first falling transition of the first input signal and the second falling transition of the second input signal.

In a third aspect, a level shifter system may include a level shifter circuit configured to generate a pair of complimentary signals in a second domain based on an input signal in a first domain. During each of a plurality of time periods, a first signal of the pair may perform a first falling transition earlier than a second signal of the pair performs a first rising transition. In addition, the second signal may perform a second falling transition earlier than the first signal performs a second rising transition. The level shifter system may further include a transition tracking circuit configured to generate an output signal having an amplitude that transitions between a high level and a low level. The transition tracking circuit may be configured to generate the output signal such that the transitions of the output signal track the earlier first falling transition performed by the first input signal and the earlier second falling transition performed by the second input signal.

In sum, a transition tracking circuit may be configured to generate an output signal having transitions that track the earlier transitions of a pair of input signals received by the transition tracking circuit. By tracking the earlier transitions, the output signal generated by the transition tracking circuit may have rise times and fall times that more closely match each other and may have a more balanced duty cycle. In addition, where the first and second signals are generated based on an initial input signal, such as an input signal to a level shifter system, delays in rising transitions and falling transitions between the output signal and the initial input signal may more closely match each other, compared to delays in rising and falling transitions between either of the pair of input signals and the initial input signal.

These and other embodiments, features, aspects and advantages of the present description will become better understood from the description herein, appended claims, and accompanying drawings.

### BRIEF DESCRIPTION OF THE DRAWINGS

The accompanying drawings, which are incorporated in and constitute a part of this specification illustrate various aspects of the invention and together with the description, serve to explain its principles. Wherever convenient, the same reference numbers will be used throughout the drawings to refer to the same or like elements.

FIG. 1 is block diagram of an example level shifter system.

FIG. 2 is a timing diagram an input signal and a pair of complimentary output signals generated by a level shifter.

FIG. 3 is a timing diagram of the input signal and the pair of complimentary output signals shown in FIG. 2, along with an output signal generated by a transition tracking circuit of FIG. 1.

FIG. 4 is circuit schematic of an example circuit configuration of the example transition tracking circuit of FIG. 1.

FIG. 5 is a timing diagram showing one of the complimentary signals inverted along with the other of the complimentary signals and the output signal shown in FIG. 3.

FIG. 6 is a circuit schematic of another example circuit configuration of the example transition tracking circuit of FIG. 1.

FIG. 7 is a timing diagram of the signals shown in FIG. 5 along with an internal delay signal.

FIG. 8 is a circuit schematic of a third example circuit configuration of the example transition tracking circuit of FIG. 1.

FIG. 9 is a timing diagram of different curves of the output signal generated by the different example circuit configurations of the transition tracking circuit.

FIG. 10 is a timing diagram of a pair of complimentary signals having earlier and/or faster rising times than falling times.

FIG. 11 is a circuit schematic of an example circuit configuration of an example transition tracking circuit configured to receive the complimentary signals of FIG. 10.

FIG. 12 is a flow chart of an example method of generating transitioning output signal.

FIG. 13 is a flow chart of an example method of generating a level-shifted output signal.

### DETAILED DESCRIPTION

Various modifications to and equivalents of the embodiments described and shown are possible and various generic principles defined herein may be applied to these and other embodiments. Thus, the claimed invention is to be accorded the widest scope consistent with the principles, features, and teachings disclosed herein.

The present description describes a transition tracking circuit that generates a transitioning output signal in response to receipt of transitioning first and second input signals, where the first input signal has an earlier falling transition than the rising transition of the second input signal, and where the second input signal has an earlier falling transition than the rising transition of the first input signal. The tracking circuit may generate the output signal such that transitions of the output signal track the earlier falling transitions. For example, when generating the output signal, the tracking circuit may initiate a rising transition of the output signal in response to the earlier falling transition of either the first input signal or the second input signal, and may initiate a falling transition of the output signal in response to the earlier falling transition of the other of the first signal or the second signal.

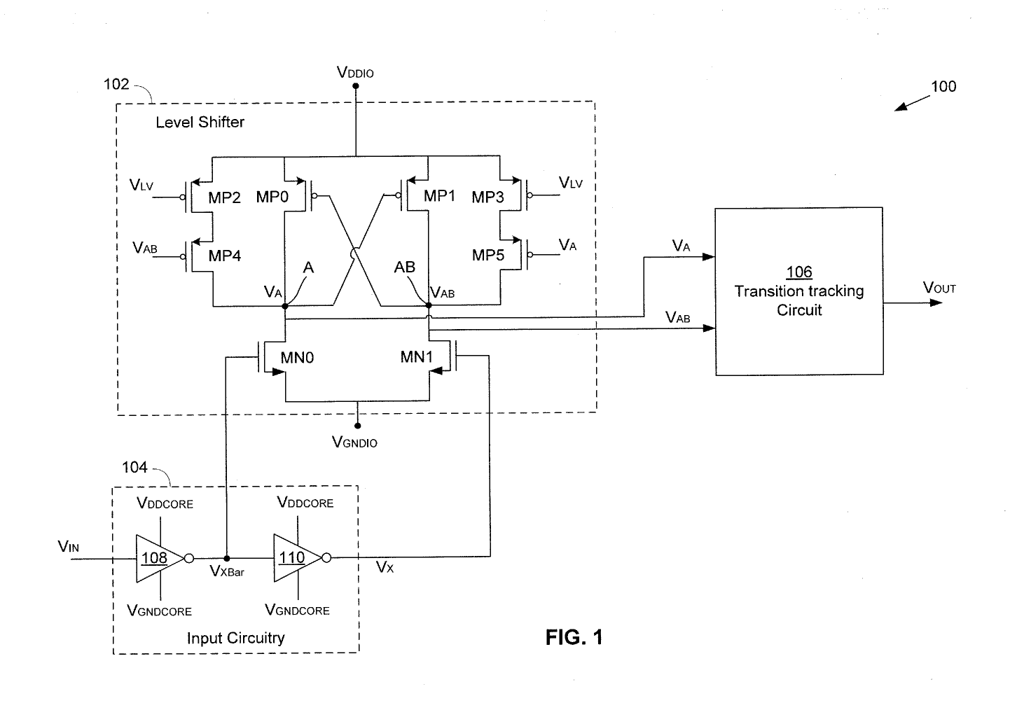

FIG. 1 is a block diagram of an example level shifter system 100 that includes a level shifter 102 in communication with input circuitry 104 and a transition tracking circuit 106. In general, the level shifter system 100 may be configured to convert an input signal V_{IN} that transitions between a high level and a low level in a first domain to an output signal V_{OUT} that transitions between a high level and a low level in a second domain. For the example level shifter system 100, the first domain may include a high voltage level V_{DDCORE} and a low voltage level V_{GNDCORE}, and the second domain may include a high voltage level V_{DDIO} and a low voltage level V_{GNDIO}. For some example level shifter applications, the level shifter system 100 may be a low-to-high level shifting system in that the high voltage level V_{DDIO} in the second domain may be higher than the high voltage level V_{DDCORE} in the first domain. Additionally, the low voltage levels V_{GNDIO}, V_{GNDCORE} may both be ground reference voltages in their respective domains. In addition, for some example level shifter applications, the high voltage level V_{DDIO} of the second domain may include multiple levels, each higher than the high voltage level V_{DDCORE} of the first domain. As an example, at some times or during some operations, the high voltage level V_{DDIO} may be a first high voltage level and at other times or during other operations, the high voltage level V_{DDIO} may be a second high voltage level, where the second high voltage level is higher than the first high voltage level. Example first and second high voltage levels may be 1.8 volts and 3.3 volts, respectively. Various levels for the first and second domains may be possible.

In general, the level shifter 102 may be any circuit configured to convert one or more input signals in a first domain to one or more output signals in a second domain. For some example circuit configurations, as shown in FIG. 1, the level shifter 102 may be a cross-coupled level shifter. The cross-coupled level shifter 102 may be configured to generate a pair of first and second complimentary signals V_{A} and V_{AB}. As shown in FIG. 1, the first complimentary signal V_{A} may be generated at a node A coupled to a drain terminal of a p-type metal-oxide-semiconductor (“PMOS”) transistor MP0, and the second complimentary signal V_{AB} may be generated at a node AB coupled to a drain terminal of a PMOS transistor MP1. The cross-coupled level shifter 102 may be considered “cross-coupled” in that a gate terminal of the PMOS transistor MP1 is coupled to the drain of the PMOS transistor MP0 and configured to receive the first complimentary signal V_{A}, and a gate terminal of the PMOS transistor MP0 is coupled to the drain of the PMOS transistor MP1 and configured to receive the second complimentary signal V_{AB}.

As shown in FIG. 1, the level shifter 102 may further include a pair of series-connected PMOS transistors MP2 and MP4 connected in parallel with the PMOS transistor MP0, and a pair of series connected PMOS transistors MP3 and MP5 connected in parallel with the PMOS transistor MP1. The pairs of series-connected PMOS transistors MP2, MP4 and MP3, MP5 may be added to the cross-coupled level shifter 102 to enable the level shifter 102 to generate the pair of first and second complimentary signals V_{A} and V_{AB} at different high levels in the second domain. As shown in FIG. 1, the PMOS transistors MP2 and MP3 may each have a gate terminal that receives a signal V_{LV}. When the level shifter 102 is to generate the pair of first and second complimentary signals V_{A}, V_{AB} at the second high level in the second domain (e.g., 3.3 volts), the signal V_{LV} may be at a level that turns off the PMOS transistors MP2, MP3 in order to deactivate the pairs of series-connected PMOS transistors MP2, MP4 and MP3, MP5. Alternatively, when the level shifter 102 is to generate the pair of first and second complimentary signals V_{A}, V_{AB} at the first high level in the second domain (e.g., 1.8 volts), the signal V_{LV} may be at a level that turns on the PMOS transistors MP2, MP3 so that the pairs of series-connected PMOS transistors MP2, MP4 and MP3, MP5 may be activated.

The cross-coupled level shifter 102 may further include an n-type metal-oxide-semiconductor (“NMOS”) transistor MN0 having a drain terminal connected to the node A and an NMOS transistor MN1 having a drain terminal connected to the node AB. Gate terminals of the NMOS transistors MN0, MN1 may be configured to receive as inputs complimentary input signals V_{X}, V_{XBar} transitioning between high and low levels V_{DDCORE}, V_{GNDCORE} of the first domain.

As shown in FIG. 1, the input circuitry 104 may be configured to generate the input signals V_{X}, V_{XBar} based on an input signal V_{IN}, which may also transition between high and low levels V_{DDCORE}, V_{GNDCORE} of the first domain. An example configuration of the input circuitry 104 may include a pair of inverters including a first inverter 108 and a second inverter 110. The first inverter 108 may be configured to receive the input signal V_{IN} and generate a first of the complimentary signals V_{XBar} and send the first complimentary signal V_{XBar} to the NMOS transistor MN0. The second inverter 110 may be configured to receive the first complimentary signal V_{XBar}, generate the second of the complimentary signals V_{X}, and send the second complimentary signal V_{X} to the NMOS transistor MN1.

The cross-coupled level shifter 102 may be a desirable low-to-high level shifter due to its high gain characteristics. However, drawbacks to the cross-coupled level shifter 102 may exist due to self-loading. By design, the NMOS transistors MN0 and MN1 may be larger than the PMOS transistors MP0-MP5. Thus, the self-loading or inherent capacitance of the NMOS transistors MN0, MN1 may include slow conversion speed and large variations in duty cycle and delay due to mismatch between rise and fall times of the first and second complimentary signals V_{A} and V_{AB} generated at the nodes A and AB, respectively. A duty cycle of a signal may generally refer to a percentage of a period or cycle of the signal in which the signal is at its high level. In a particular timing relationship, the first and second complimentary signals V_{A} and V_{AB} may perform their falling transitions faster than they perform their rising transitions. Accordingly, each of the first and second complimentary signals V_{A} and V_{AB} may perform their falling transition faster and/or earlier than the other performs its rising transition.

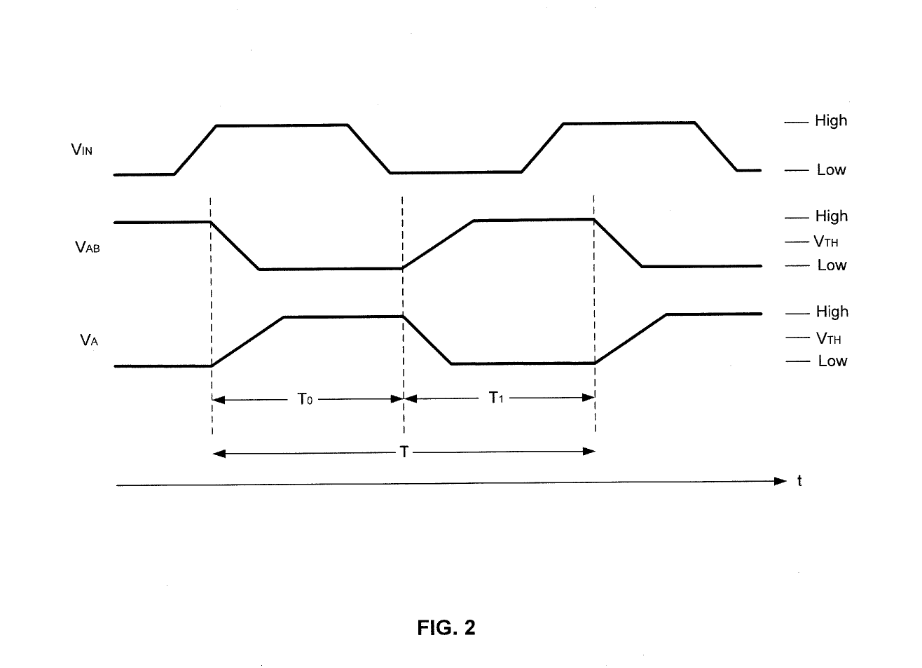

FIG. 2 shows a timing diagram of example amplitudes of the input signal V_{IN} and the first and second complimentary signals V_{A} and V_{AB} as a function of time t, illustrating the mismatch in rise time, fall time, and duty cycle. Amplitudes of the input signal V_{IN} and the first and second complimentary signals V_{AB}, V_{A}, may transition between a respective high voltage level (denoted as “High” in FIG. 2) and a respective low voltage level (denoted as “Low” in FIG. 2). The high and low levels of the input signal V_{IN} may be in the first domain, that is, V_{DDCORE} and V_{GNDCORE}, and the high and low levels of each of the complimentary signals V_{AB}, V_{AN} may be in the second domain, that is, V_{DDIO} and V_{GNDIO}.

Each of the signals V_{IN}, V_{A}, V_{AB} may transition during a plurality of cycles. FIG. 2 shows a time period T corresponding to a single cycle, during which each of the complimentary signal V_{A} and V_{AB} may cycle through one rising transition and one falling transition. A rising transition may occur when the amplitude transitions from a low level to a high level. A falling transition may occur when the amplitude transitions from the high level to the low level. As used in the present description, a cycle may refer or correspond to a period of time in which a signal performs a rising transition and a falling transition. For example, a signal may perform a rising transition and falling transition during a current cycle and then perform a next rising transition and falling transition during a next cycle. The time periods that elapse during sequential cycles may be the same as or different from each other. Accordingly, as used herein, the term “cycle,” does not necessarily refer to or mean that the signals are periodic or otherwise oscillate at an associated frequency.

In addition, as shown in FIG. 2, the first and second complimentary signals V_{A} and V_{AB} may inversely track each other in that the first complimentary signal V_{A} may perform a rising transition around the same time that the second complimentary signal V_{AB} performs a falling transition, and vice versa. That is, during a first portion T₀ of the time period T, the first complimentary signal V_{A} may perform a rising transition and the second complimentary signal V_{AB} may perform a falling transition. In addition, during a second portion T₁, the first complimentary signal V_{A} may perform a falling transition and the second complimentary signal V_{AB} may perform a rising transition.

However, during each of the first portion T₀ and the second portion T₁, the first rising and falling transitions of the first and second complimentary signals V_{A} and V_{AB} may not exactly inversely track each other. That is, during each of the first and second portions T₀, T₁, one of the signals V_{A}, V_{AB} may perform its transition before the other. In a particular timing relationship, during each of the first and second portions T₀, T₁, the signal performing its falling transition may perform it earlier than the other signal performs its rising transition. As shown in FIG. 2, during the first portion T₀, the second complimentary signal V_{AB} may perform its falling transition before the first complimentary signal V_{A} performs its rising transition, and during the second portion T₁, the first complimentary signal V_{A} may perform its falling transition before the second complimentary signal V_{AB} performs its rising transition.

For other example level shifter systems that use the level shifter 102, one of the complimentary signals V_{A} or V_{AB} may be used for downstream processing. However, due to the mismatch in rise times and fall times, neither the first complimentary signal V_{A} or the second complimentary signal V_{AB} may have a duty cycle that matches or at least that is within a desirable percentage of the duty cycle of the input signal V_{IN}, which may have a target or desired duty cycle, such as a 50% duty cycle.

An indication of the duty cycle mismatch may be the different delays that are incurred when each of the first and second complimentary signals V_{A}, V_{AB} perform their respective transitions relative to when the input signal V_{IN} performs its transitions. For example, taking the first complimentary signal V_{A} and the input signal V_{IN}, the delay from when the input signal V_{IN} performs its rising transition to when the first complimentary signal V_{A} performs its rising transition may vary significantly compared to the delay from when the input signal V_{IN} performs its falling transition to when the first complimentary signal V_{A} performs its falling transition. This difference in delay may provide a duty cycle of the first complimentary signal V_{A} that may be undesirable, particularly for corner cases. Similarly, taking the second complimentary signal V_{AB} and the input signal V_{IN}, the delay from when the input signal V_{IN} performs its rising transition to when the second complimentary signal V_{AB} performs its falling transition may vary significantly compared to the delay from when the input signal V_{IN} performs its falling transition to when the second complimentary signal V_{AB} performs its rising transition. This difference in delay may provide a duty cycle of the second complimentary signal V_{AB} that may be undesirable, particularly for corner cases.

Such mismatch in the duty cycle and delay may degrade performance of downstream circuitry that uses either or both of the first and second complimentary signal V_{A}, V_{AB} for subsequent processing. To improve the delay and duty cycle, the level shifter system 100 may include the transition tracking circuit 106, which may receive the first and second complimentary signals V_{A} and V_{AB} and generate the output signal V_{OUT} such that the rising and falling transitions of the output signal V_{OUT} track the faster and/or earlier falling transitions of each of the first and second complimentary signals V_{A} and V_{AB}. In other words, the transition tracking circuit may respond to and/or “select” the faster and/or earlier falling transition by beginning either a falling or rising transition of the output signal V_{OUT} upon detecting the earlier falling transition. The resulting output signal V_{OUT} may have a duty cycle that more closely matches a duty cycle of the input signal V_{IN} and with rise and fall times that more closely match each other, compared to the rise and fall times of the output signals V_{A} and V_{AB} generated by the level shifter circuit 102.

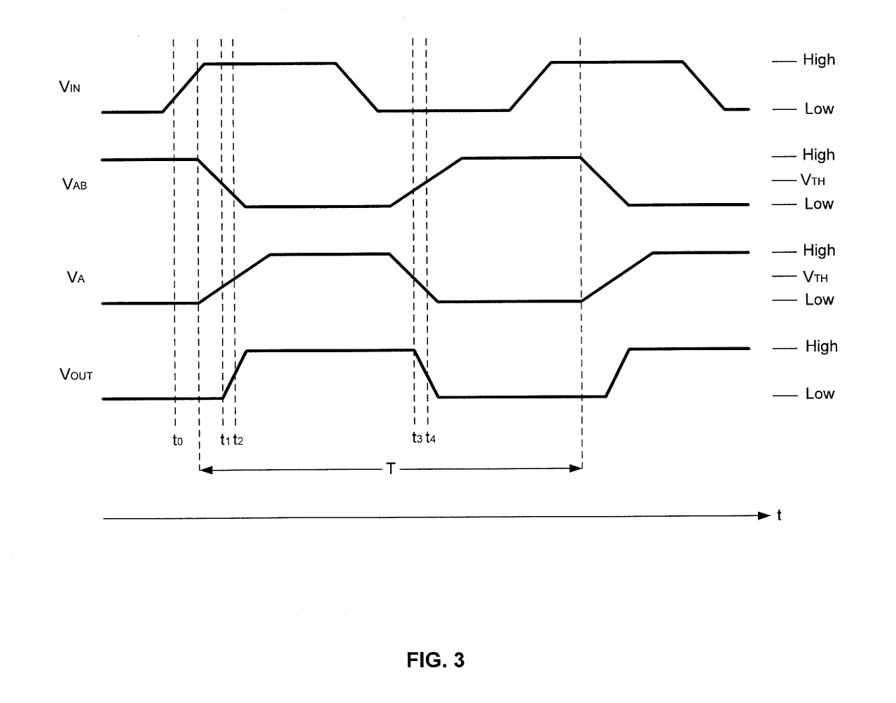

With the transition tracking circuit 106, the level shifter system 100 may output the output signal V_{OUT} generated by the transition tracking circuit 106 for downstream processing rather than either of the signals V_{A} or V_{AB}. In this sense, the transition tracking circuit may be considered a second stage of a level shifter. The first stage may be the level shifter 102, which converts input complimentary signals V_{X}, V_{Xbar} in a first domain to output complimentary signals V_{A}, V_{AB} in a second domain, and the second stage may be the transition tracking circuit 106, which tracks the faster and/or earlier falling transitions of the complimentary signals V_{A}, V_{AB} to generate an output signal V_{OUT} in the second domain. Generation of the output signal V_{OUT} by the transition tracking circuit 106 is described in further detail with reference to FIG. 3.

FIG. 3 shows a timing diagram of example amplitudes of the input signal V_{IN} the first and second input signals V_{A}, V_{AB} as shown in FIG. 2, and further with the output signal V_{OUT} as a function of time t, as received and generated by the transition tracking circuit 106. Like the complimentary signals V_{A}, V_{AB}, the amplitude of the output signal V_{OUT} may transition between a respective high voltage level and a respective low voltage level (denoted as “Low” in FIG. 2). The high and low levels of the output signal V_{OUT} may be in the second domain.

When the first and second complimentary signals V_{A}, V_{AB} perform a transition (either rising or falling), there is a beginning time when the transition begins and an end time when the transition ends. In addition to the beginning time and the end time, there may also be a response time at which the amplitude is at a threshold level V_{TH} that causes a component of the transition tracking circuit 106 receiving one of complimentary signals V_{A} or V_{AB} at the threshold level V_{TH} to change or alter its response to the complimentary signal V_{A} or V_{AB}. For example, as described in more detail below, a component of the transition tracking circuit 100 may include a switch that receives one of the complimentary signals V_{A} or V_{AB}. The response time may be a time during a transition at which the amplitude reaches a threshold level V_{TH} causing the switch to turn on or turn off. The response time may occur during the transition before the end time, as shown in FIG. 3, or may occur simultaneously with the end time, depending on the components of the transition tracking circuit 100 and their corresponding characteristics. As used herein, and unless expressly described otherwise, the first and second complimentary signals V_{A}, V_{AB} may be considered to “perform a transition” (either rising or falling), when their respective amplitudes reach a threshold level V_{TH} that causes a component receiving the first or second complimentary signal V_{A}, V_{AB} to change its response to the respective first or second complimentary signal V_{A}, V_{AB}.

As shown again in FIG. 3, during the time period T, the second complimentary signal V_{AB} may perform its falling transition, which occurs at time t₁, earlier than the first complimentary signal V_{A} performs its rising transition, which occurs at time t₂. In addition, the first complimentary signal V_{A} may perform its falling transition, which occurs at time t₃, earlier than the first input signal V_{AB} performs its rising transition, which occurs at time t₄.

The transition tracking circuit 106 may generate the output signal V_{OUT} such that the output signal V_{OUT} begins a transition in response to the earlier of the two transitions. That is, the transition tracking circuit 106 may be configured to generate the output signal V_{OUT} such that the transitions of the output signal V_{OUT} track the earlier transitions and independent of the later transitions of the first and second complimentary signals V_{A}, V_{AB}.

For example, as shown in FIG. 3, in response to the second complimentary signal V_{AB} performing an earlier falling transition at time t₁, the output signal V_{OUT} may begin a rising transition. The output signal V_{OUT} may begin its rising transition even though the first complimentary signal V_{A} is still at its low level and/or has not yet performed its rising transition, which occurs at the later time t₂. In this regard, the transition tracking circuit 106 may begin the rising transition of the output signal V_{OUT} in response to performance of the earlier falling transition of the second complimentary signal V_{AB} at the time t₁ and independent of the later rising transition of the first complimentary signal V_{A} at time t₂.

Similarly, in response to the first complimentary signal V_{A} performing an earlier falling transition at time t₃, the output signal V_{OUT} may begin a falling transition. The output signal V_{OUT} may begin its falling transition even though the second complimentary signal V_{AB} is still at its low level and/or has not yet performed its rising transition, which occurs at the later time t₄. In this regard, the transition tracking circuit 106 may begin the falling transition of the output signal V_{OUT} in response to performance of the earlier falling transition of the first complimentary signal V_{A} at the time t₃ and independent of the later rising transition of the second complimentary signal V_{AB} at time t₄.

By tracking the earlier falling transitions instead of and/or independent of the later rising transitions of the first and second complimentary signals V_{A}, V_{AB}, the output signal V_{OUT} may be generated to have a duty cycle that more closely matches the duty cycle of the input signal V_{IN}. In FIG. 3, the input signal V_{IN} has a duty cycle at or relatively close to 50%, and each of the first and second complimentary signals V_{A}, V_{AB} have duty cycles noticeably lower than 50% (i.e., their respective amplitudes are at low levels longer than they are at high levels). By tracking the earlier falling transitions of the complimentary signals V_{A}, V_{AB}, the transition tracking circuit 106 may generate the output signal V_{OUT} to have a duty cycle that more closely matches the 50% duty cycle of the input signal V_{IN} than the duty cycles of either of the first or second complimentary signals V_{A}, V_{AB}. In addition, the rise and fall times of the output signal V_{OUT} may more closely match each other, compared to the rise and fall times of the first and second complimentary signals V_{A}, V_{AB}.

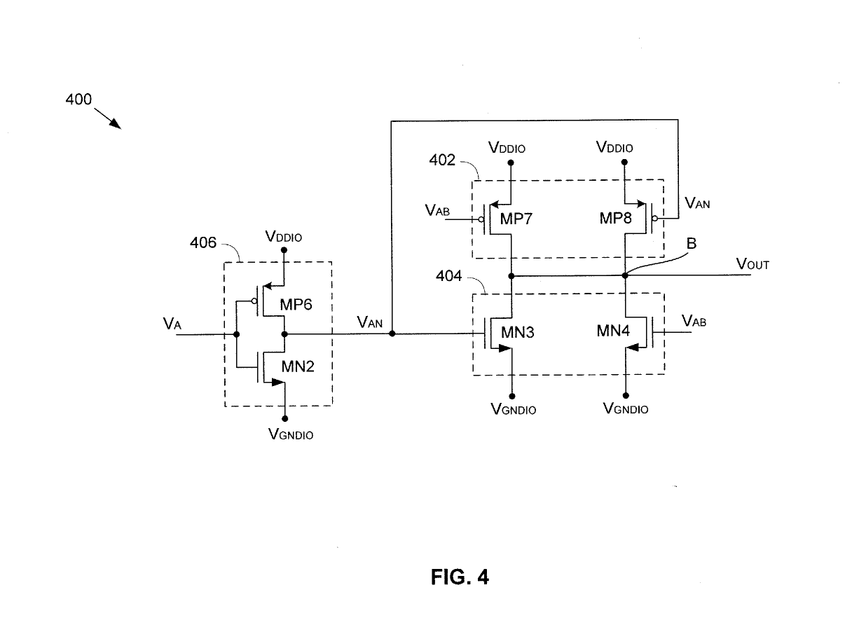

FIG. 4 shows a circuit schematic of an example circuit configuration 400 of the transition tracking circuit 106. The example circuit configuration 400 may include an output node B at which the output signal V_{OUT} is generated and output. The example circuit configuration 400 may further include pull-up and pull-down circuitry that includes a pull-up circuit 402 and a pull-down circuit 404, each connected or tied to the output node B. The pull-up circuit 402 may be configured to pull up the output signal V_{OUT} to its high level in response to the earlier falling transition of the second complimentary signal V_{AB}. The pull-down circuit 404 may be configured to pull down the output signal V_{OUT} to its low level in response to the earlier falling transition of the first complimentary signal V_{A}.

As shown in FIG. 4, the example circuit configuration 400 may also include an inverter circuit 406 configured to receive the first complimentary signal V_{A} from the level shifter 102. Based on the first complimentary signal V_{A}, the inverter circuit 406, may generate and output an inverted first complimentary signal V_{AN}. FIG. 4 shows the inverter circuit 406 configured as a push-pull or totem pole circuit including a PMOS transistor MP6 and an NMOS transistor MN2, although other circuit configurations for the inverter circuit 406 may be possible.

The pull-up circuit 402 may be configured to operate in a pull-up mode and a floating mode. In the pull-up mode, the pull-up circuit 402 may be configured to pull up and/or maintain the output signal V_{OUT} at its high level. In the floating mode, the pull-up circuit 402 may not operate to pull up and/or may be prevented from pulling up the output signal V_{OUT}.

As shown in FIG. 4, the pull up circuit 402 may include a first PMOS transistor MP7 configured to turn on and turn off. The first PMOS transistor MP7 may have a source terminal connected to a voltage V_{DDIO} and a drain terminal connected to the output node B. The first PMOS transistor MP7 may also have a gate terminal, which may be a first input terminal for the example circuit configuration 400 and configured to receive the first input signal V_{AB}. When the first input signal V_{AB} is at its high level or at least a level greater than its threshold voltage V_{TH}, the first PMOS transistor MP7 may be turned off. When the first input signal V_{AB} is at or below its threshold level V_{TH}, the PMOS transistor MP7 may be turned on.

The pull-up circuit 402 may further include a second PMOS transistor MP8 connected in parallel with the first PMOS transistor MP7. As shown in FIG. 4, the second PMOS transistor MP8 may be configured to receive the inverted first complimentary signal V_{AN} at its gate terminal. In addition, like the first PMOS transistor MP7, the second PMOS transistor MP8 may have its source terminal connected to the source voltage V_{DDIO} and its drain terminal connected to the output node B at which the output voltage V_{OUT} is generated and output.

By being connected in parallel with each other, the first and second PMOS transistors MP7, MP8 may be configured to pull up the output signal V_{OUT} independent of each of each other. Accordingly, when one or both of the first and second PMOS transistors MP7, MP8 is turned on, the pull-up circuit 402 may be configured in the pull-up mode to pull up the level of the output signal V_{OUT}. Alternatively, when both of the first and second PMOS transistors MP7, MP8 are turned off, the pull-up circuit 402 may be configured in the floating mode.

In addition, for some example configurations, one of the first and second PMOS transistors MP7, MP8 may be “stronger” than the other, in that the stronger PMOS transistor may draw more current, have a larger gate width, and/or pull up the output signal V_{OUT} to its high level faster than the weaker PMOS transistor. For other example configurations, the first and second PMOS transistors MP7, MP8 may be about equal in strength.

The pull-down circuit 404 may be configured to operate in a pull-down mode and a floating mode. In the pull-down mode, the pull-down circuit 404 may be configured to pull down and/or maintain the output signal V_{OUT} at its low level. In the floating mode, the pull-down circuit 404 may not operate to pull down and/or may be prevented from pulling down the output signal V_{OUT}.

As shown in FIG. 4, the pull-down circuit 404 may include a first NMOS transistor MN3, and a second NMOS transistor MN4 connected in parallel with the first NMOS transistor MN3. Each of the first and second NMOS transistors MN3, MN4 may have a drain terminal connected to the output node B and a source terminal connected to the ground reference voltage V_{GNDIO}. In addition, the first NMOS transistor MN3 may have a gate terminal configured to receive the inverted first complimentary signal V_{AN}, and the second NMOS transistor MN4 may have a gate terminal configured to receive the second complimentary signal V_{AB}. The first NMOS transistor MN3 may be configured to turn on when the inverted first complimentary signal V_{AN} reaches or exceeds its threshold level V_{TH}, and may be configured to turn off when the inverted first complimentary signal V_{AN} is below its threshold level V_{TH}. The second NMOS transistor MN4 may be configured to turn on when the second complimentary signal V_{AB} reaches or exceeds its threshold level V_{TH}, and may be configured to turn off when the second complimentary signal V_{AB} is below its threshold level V_{TH}.

By being connected in parallel with each other, the first and second NMOS transistors MN3, MN4 may be configured to pull down the output signal V_{OUT} independent of each of each other. Accordingly, when one or both of the first and second NMOS transistors MN3, MN4 is turned on, the pull-down circuit 404 may be configured in the pull-down mode to pull down the level of the output signal V_{OUT}. Alternatively, when both of the first and second NMOS transistors MN3, MN4 are turned off, the pull-down circuit 404 may be configured in the floating mode.

In addition, for some example configurations, one of the first and second NMOS transistors MN3, MN4 may be “stronger” than the other, in that the stronger NMOS transistor may draw more current, have a larger gate width, and/or pull down the output signal V_{OUT} to its low level faster than the weaker NMOS transistor. For other example configurations, the first and second NMOS transistors MN3, MN4 may be about equal in strength.

Further, the first PMOS transistor MP7 and the first NMOS transistor MN3 may form and/or be part of a first path of series connected transistors, and the second PMOS transistor MP8 and the second NMOS transistor MN4 may form and/or be part of a second path of series connected transistors. Each of the first path and the second path may be part of the forward or input-to-output path of the circuit configuration 400, and so the first and second paths of series connected transistors may be referred to as a first forward path and a second forward path, respectively. Additionally, for configurations where one of the PMOS transistors MP7, MP8 is stronger than the other, and one of the NMOS transistors MN3, MN4 is stronger than the other, the stronger PMOS and NMOS transistor may be part of the same path, and the weaker PMOS and NMOS transistors may be part of the same path. For the example circuit configuration 400 shown in FIG. 4, the PMOS transistor MP7 and the NMOS transistor MN3 may be the stronger transistors and form the stronger, first forward path, and the PMOS transistor MP8 and the NMOS transistor MN4 may be the weaker transistors and form the weaker, second forward path. As explained in further detail below, the stronger, first forward path may be the dominant path of transistors to pull up and pull down the level of the output signal V_{OUT}. The weaker, second forward path may assist the stronger, first path in pulling up or pulling down the level of the output signal V_{OUT} and/or may function as a control latch that maintains the level of the output signal V_{OUT} at its high level or low level in the event that the stronger, first forward path is floating relative to the output node B.

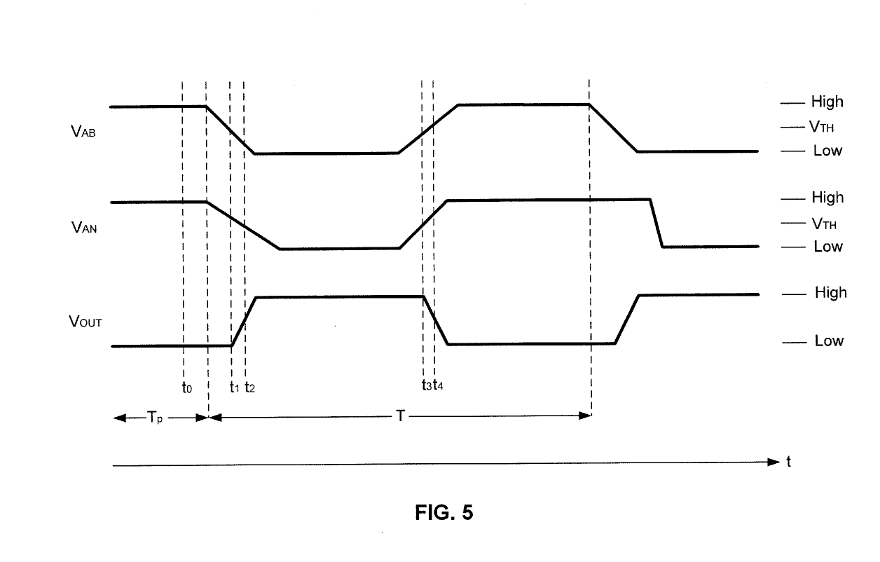

Operation of the pull-up and pull-down circuits 402, 404 of the example circuit configuration 400 to generate the output signal V_{OUT} is made with reference to FIG. 5, which shows a timing diagram of the amplitudes of the second complimentary signals V_{AB}, the inverted first complimentary signal V_{AN}, and the output signal V_{OUT}. At an initial time t₀ during a prior time period Tₚ, each of the signals V_{AB}, V_{AN} may be at their respective high levels. Accordingly, the first and second PMOS transistors MP7, MP8 may be turned off, configuring the pull-up circuit 402 in the floating mode, and the first and second NMOS transistor MN3, MN4 may be turned on, configuring the pull-down circuit 404 in the pull-down mode. With the pull-up circuit 402 in the floating mode and the pull-down circuit 404 in the pull down mode, the output signal V_{OUT} may be pulled down to its low level, as shown in FIG. 5.

At time t₁, the second complimentary signal V_{AB} may perform a falling transition, which may turn on the first PMOS transistor MP7 and turn off the second NMOS transistor MN4. Accordingly, the pull-up circuit 402 may change from being configured in the floating mode to the pull-up mode. In addition, at time t₁, the inverted first complimentary signal V_{AN} may not yet have performed its falling transition, and so the first NMOS transistor MN3 may remain turned on, keeping the pull-down circuit 404 in the pull-down mode. As such, at time t₁, the pull-up circuit 402 may be in its pull-up mode pulling up the level of the output signal V_{OUT} to its high level while the pull-down circuit 404 may be in its pull-down mode pulling down the level of the output signal V_{OUT} to its low level. The pull-up and pull-down circuits 402, 404 simultaneously being in their respective pull-up and pull-down modes may be referred to as contention between the pull-up and pull-down circuits 402, 404. Contention between the pull-up and pull-down circuits may cause the level of the output signal V_{OUT} to be somewhere in between its high and low levels. Since the output signal V_{OUT} was at its low level prior to t₁, then at t₁ when the first PMOS transistor MP7 turns on, the level of the output signal V_{OUT} may begin to increase, as shown in FIG. 5. As such, when the second complimentary signal V_{AB} performs the earlier falling transition, the example circuit configuration 400 may respond by beginning to increase the level of the output signal V_{OUT} from the low level, and irrespective of the first complimentary signal V_{A} not yet having performed its later rising transition.

At time t₂, the inverted first complimentary signal V_{AN} may perform the later falling transition, which may turn off the first NMOS transistor MN3 and turn on the second PMOS transistor MP8. In addition, at time t₂, the first input signal V_{AB} is below its threshold level V_{TH}, and so the first PMOS transistor MP7 remains turned on and the second NMOS transistor remains turned off. Accordingly, with both the first NMOS transistor MN3 and the second NMOS transistor MN4 turned off, the pull-down circuit 404 may be configured in the floating mode. In addition, the pull-up circuit 402 may remain in the pull up with both the first and second NMOS transistors MP7, MP8 turned on. As such, at time t₂, the pull-up circuit 402 may continue pulling up the level of the output signal V_{OUT} to the high level without being in contention with the pull-down circuit 404.

The first and second input signals V_{AB}, V_{AN} may remain at the their respective low levels, and the output signal V_{OUT} may remain at its high level until time t₃ when the second input signal V_{AN} performs the earlier rising transition. In response, the first NMOS transistor MN3 may turn on and the second PMOS transistor may turn off. With the first NMOS transistor MN3 turning on, the pull-down 404 circuit may change from being in the floating mode to the pull-down mode. In addition, at time t₃, the first input signal V_{AB} may not yet have performed its rising transition, and so even though the second PMOS transistor MP8 may turn off, the first PMOS transistor MP7 may still be turned on, and so the pull-up circuit 402 may remain in the pull-up mode. As such, at time t₃, the pull-up and pull-down circuits 402, 404 may be in contention, causing the level of the output signal V_{OUT} to begin decreasing from its high level to a level in between the high and low levels of the output signal V_{OUT}, as shown in FIG. 5. As such, when the first complimentary signal V_{A} performs its earlier falling transition (and the inverted first complimentary signal V_{AB} performs the earlier rising transition), the example circuit configuration 400 may respond by beginning to decrease the level of the output signal V_{OUT} from the high level, and irrespective of the second complimentary signal V_{AB} not yet having performed its later rising transition.

At time t₄, the second complimentary signal V_{AB} may perform the later rising transition. In response, the first PMOS transistor MP7 may turn off and the second NMOS transistor MN4 may turn on. In addition, at time t₄, the inverted second input signal V_{AN} may still be above its threshold voltage V_{TH}, and so the first NMOS transistor MN3 may still be turned on and the second PMOS transistor MP8 may still be turned off. With the first and second NMOS transistor MP7, MP8 both turned off, the pull-up circuit 402 may be in the floating mode. In addition, with the first and second NMOS transistors MN3, MN4 both turned on, the pull-down circuit 404 may remain in the pull down mode. As such, at time t₄, the pull-down circuit 404 may continue to pull down the level of the output signal V_{OUT} to the low level without being in contention with the pull-up circuit 402.

After time t₄, the first and second input signals V_{AB}, V_{AN} may be at respective high levels and the output signal V_{OUT} may be at its low level for the remainder of the time cycle (i.e., time period T) until a next cycle at time t₅ when the second complimentary signal V_{AB} begins to perform its earlier falling transition.

Referring back to FIG. 4, the first and second PMOS transistors MP7, MP8 and the first and second NMOS transistors MN3, MN4 forming the first and second paths may be referred to as a “mixer” circuit in the sense that transistors MP7, MP8, MN3, MN4 are configured to “mix” the earlier falling transitions of the first and second complimentary signals V_{A}, V_{AB} output from the level shifter 102 to generate the output signal V_{OUT}.

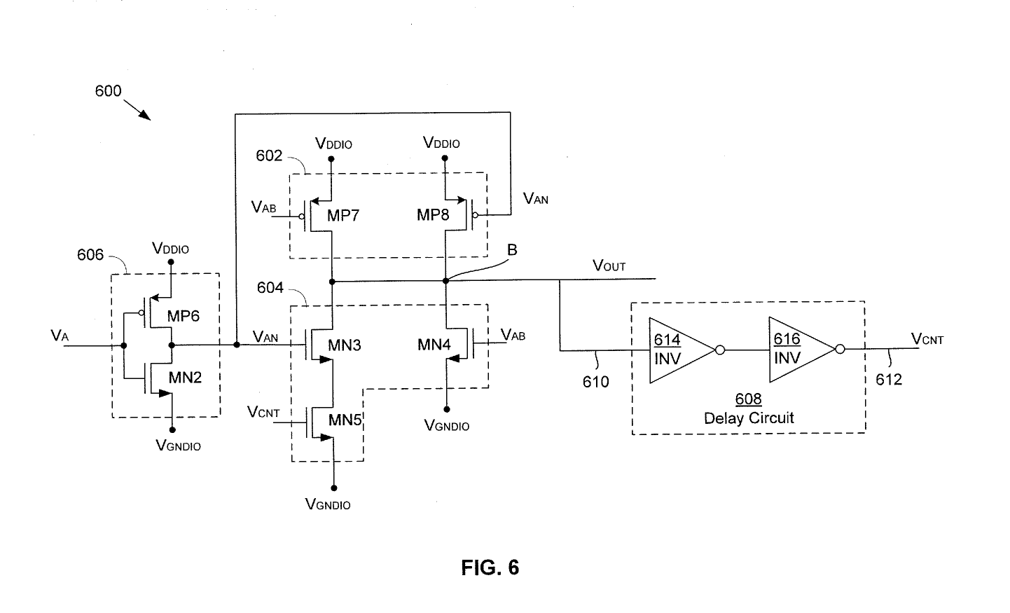

FIG. 6 shows another example circuit configuration 600 of the transition tracking circuit 100. Similar to the example circuit configuration 400, the example circuit configuration 600 may include pull-up and pull-down circuits 602, 604, and an inverter circuit 606. The inverter circuit 606 may be configured to receive and invert the first complimentary signal V_{A} to generate an inverted first complimentary signal V_{AN}. The pull-up and pull-down circuits 602, 604 may be configured to respectively pull up and pull down the output signal V_{OUT} in response to the earlier falling transitions of the first and second complimentary signals V_{A}, V_{AB}.

In addition, like the pull-up and pull-down circuits 402 and 404, the pull-up circuit 602 may include the first PMOS transistor MP7 connected in parallel with the second PMOS transistor MP8, and the pull-down circuit 604 may include the first NMOS transistor MN3 connected in parallel with the second NMOS transistor MN4. The first PMOS and NMOS transistors MP7, MN3 may be the stronger transistors and part of a first path of series connected transistors. The second PMOS transistor MP8 and the second NMOS transistor MN4 may be the weaker transistors and part of a second path of series connected transistors. Further, the first PMOS transistor MP7 and the second NMOS transistor MN4 may be configured to receive at their respective gate terminals the second complimentary signal V_{AB}. The second PMOS transistor MP8 and the first NMOS transistor MN3 may be configured to receive at their respective gate terminals the inverted first complimentary signal V_{AN}.

The example circuit configuration 600 may include circuitry in addition to the first and second PMOS transistors MP7, MP8 and the first and second NMOS transistors MN3, MN4, which may reduce contention between the pull-up and pull-down circuits 602, 604, as compared to the contention between the pull-up and pull-down circuits 402, 404 of FIG. 4. In particular, the pull-down circuit 604 may further include a third NMOS transistor MN5 connected in series with the first NMOS transistor MN3. In further detail, for the example configuration shown in FIG. 6, the third NMOS transistor MN5 may have a drain terminal connected to the source terminal of the first NMOS transistor MN3 and a source terminal connected to a ground reference voltage V_{GNDIO}. By being connected in series with the first NMOS transistor MN3, the third NMOS transistor MN5 may be part of the first path of series connected transistors.

Additionally, by being connected in series with each other, the first and third NMOS transistors MN3, MN5 may be configured to pull down the output signal V_{OUT} to its low level when both of the first and third NMOS transistors MN3, MN5 are turned on. Alternatively, when one or both of the first and third NMOS transistors MN3, MN5 is turned off, the series connection of the first and third NMOS transistors MN3, MN5 may be floating and configured not to pull down the output signal V_{OUT}. In addition, with the second NMOS transistor MN4 being connected in parallel with the series connection of the first and third NMOS transistors MN3, MN5, the pull-down circuit 604 may be configured in the pull-down mode when either the series connection of the first and third NMOS transistors MN3, MN5 is turned on or the second NMOS transistor MN4 is turned on. Alternatively, when both the series connection of the first and third NMOS transistors MN3, MN5 and the second NMOS transistor MN4 is turned off, the pull-down circuit 604 may be configured in the floating mode.

In addition, as shown in FIG. 6, the second NMOS transistor MN5 may have a gate terminal configured to receive and turn on and off in response to a delayed version V_{CNT} of the output signal V_{OUT}. The example circuit configuration 600 may further include a delay circuit 608 configured to generate the delayed version V_{CNT} of the output signal V_{OUT}. The delay circuit 608 may have an input 610 connected to the output node B and configured to receive the output signal V_{OUT}. In response to receipt of the output signal V_{OUT}, the delay circuit 608 may be configured to generate and output the delayed version V_{CNT} of the output signal V_{OUT} at its output 612. In one example configuration, the delay circuit 608 may include a chain of inverters (INV), each with an associated delay or latency when generating an inverted output. An overall delay of the delay circuit 608 may be and/or correspond to a sum of the individual delays of the inverters in the chain.

For the example configuration shown in FIG. 6, the chain of inverters may include a first inverter 614 configured to receive the output signal V_{OUT} and a second inverter 616 configured to receive an inverted output from the first inverter 614. The inverted output of the second inverter 616 may be the delayed output signal V_{CNT} of the delay circuit 608. Other example configurations of the delay circuit 406 may include more than two inverters. Generally, though, the number of inverters may be an even number so that the delayed output signal V_{CNT} directly tracks the output signal V_{OUT}. That is, when the output signal V_{OUT} performs a rising transition, a next transition of the delayed output signal V_{CNT} is a rising transition, and when the output signal V_{OUT} performs a falling transition, a next transition of the delayed output signal V_{CNT} is a falling transition. In still other example configurations of the delay circuit 608, circuitry other than or in addition to a chain of inverters may be used to generate and output a delayed version V_{CNT} of the output signal V_{OUT}.

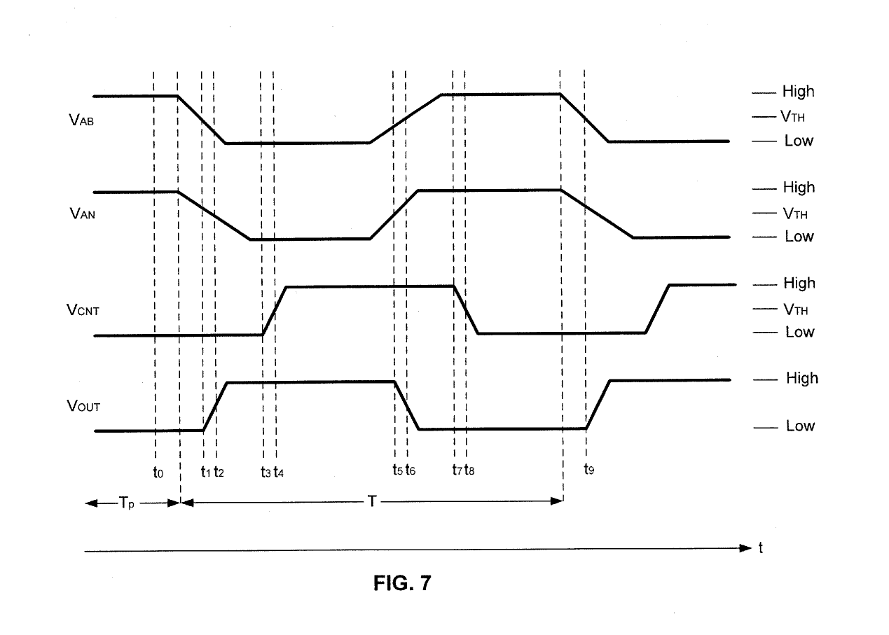

Operation of the example circuit configuration 600 is made with reference to FIG. 7, which is a timing diagram of FIG. 5, showing amplitudes of the second complimentary signal V_{AB}, the inverted first complimentary signal V_{AN}, and the output signal V_{OUT} as shown in FIG. 5, and further showing the amplitude of the delayed output signal V_{CNT} as functions of time t.

At an initial time t₀ during a prior time period Tₚ, shortly before the beginning of a cycle (i.e, the time period T) when the second complimentary signal V_{AB} begins a falling transition, the second complimentary signal V_{AB} and the inverted first complimentary signal V_{AN} may be at their respective high levels. The output signal V_{OUT} may be at its low level. The delayed output signal V_{CNT} may also be at its low level. Each of the first and second PMOS transistors MP7, MP8 may be turned off, and so the pull-up circuit 402 may be in the floating mode. The first NMOS transistor MN3 may be turned on, the third NMOS transistor MN5 may be turned off, and the second NMOS transistor MN4 may be turned on. Accordingly, the pull-down circuit 604 may be in the pull-down mode, pulling down the output voltage V_{OUT} to its low level. In addition, since the first PMOS transistor MP7 and the third NMOS transistor MN5 are turned off, the output node B may be floating relative to the first path. Also, since the second PMOS transistor MP8 may be turned off and the second NMOS transistor MN4 may be turned on, the second path may operate to pull down and/or maintain the output signal V_{OUT} at its low level.

At a time t₁, the second complimentary signal V_{AB} may perform the earlier falling transition. In response, the first PMOS transistor MP7 may turn on, configuring the pull-up circuit 602 in the pull up mode. In addition, the second PMOS transistor MN4 may turn off, configuring the pull-down circuit 404 in the floating mode. With reference to the first path, even though the first NMOS transistor MN3 is turned on, since the third NMOS transistor MN5 is turned off, there may be no contention in the first path. With reference to the second path, both the second PMOS transistor MP8 and the second NMOS transistor MN4 may be turned off, and so the output node B may be floating relative to the second path. Accordingly, in response to the earlier falling transition of the second complimentary signal V_{AB} at time t₁, the pull-up circuit 602 may begin pulling up the output signal V_{OUT} without contention from the pull-down circuit 604. Without contention from the pull-down circuit 604, the pull-up circuit 602 may pull-up the output signal V_{OUT} more quickly than with contention.

At a time t₂, the inverted first complimentary signal V_{AN} may perform the later falling transition. In response, the second PMOS transistor MP8 may turn on, and the first NMOS transistor MN3 may turn off. The pull-up circuit 602 and the pull-down circuit 604 may remain in their respective pull-up and floating modes, and the output signal V_{OUT} may continue rising to its high level.

At time t₃, the delayed output signal V_{CNT} may begin rising in accordance with the delay of the delay circuit 606. At time t₄, the delayed output signal V_{CNT} may reach a threshold level V_{TH} to turn on the third NMOS transistor MN5. However, the first NMOS transistor MN3 may remain turned off, and so the series connection of the first and third NMOS transistors MN3, MN5 may remain floating relative to the output node B.

As shown in FIG. 7, the delayed output signal V_{CNT} does not reach its threshold level V_{TH} until a time t₄ occurring after time t₂ when the inverted first complimentary signal V_{AN} performs its later falling transition. If the delayed output signal V_{CNT} increased to its threshold level V_{TH} before time t₂, then both the first and third NMOS transistors MN3, MN5 would be turned on, creating contention with the first PMOS transistor MP7 in the first path. To avoid contention in the first path between times t₁ and t₂, the delay circuit 608 has a delay such that the delayed output signal V_{CNT} does not increase to its threshold level V_{TH} to turn on the third NMOS transistor MN5 until after the inverted first complimentary signal V_{AN} performs its falling transition.

At a time t₅, the inverted first complimentary signal V_{AN} may perform its earlier rising transition. In response, the second PMOS transistor MPS may turn off and the first NMOS transistor MP3 may turn on. However, at time t₅, the second complimentary signal V_{AB} is still at its low level, and so the first PMOS transistor MP7 may remain turned on. Accordingly, the pull-up circuit 602 may remain in the pull up mode. In addition, when the first NMOS transistor MP3 turns on, both the first NMOS transistor MN3 and the third NMOS transistor MN5 are turned on, and so the pull-down circuit 604 may be in the pull-down mode. Accordingly, at time t₅, there may be contention between the pull-up circuit 602 and the pull-down circuit 604. With regard to the first and second paths, the output node B may be in contention relative to the first path, and may be floating relative to the second path. Since the output signal V_{OUT} was at its high level prior to the inverted first complimentary signal V_{AN} performing its earlier rising transition at time t₅, the output signal V_{OUT} may begin decreasing to a level in between its high level and low level. In addition, the series connection of the first NMOS transistor MN3 and the third NMOS transistor MN5 may operate to pull down the output signal V_{OUT} more quickly and/or sooner than if only the first NMOS transistor MN3 was included in the first path to pull down the output signal V_{OUT}. As such, even though there is contention at time t₅, the addition of the third NMOS transistor MN5 to the pull-down circuit 604 may reduce the amount of contention.

At time t₆, the first input signal V_{AB} may perform its later rising transition. In response, the first PMOS transistor MP7 may turn off, configuring the pull-up circuit 602 in the floating mode. In addition, the second NMOS transistor MN4 may turn on and the pull-down circuit 604 may remain in pull-down mode. Contention may be removed in the first path at time t₆ due to the first PMOS transistor MP7 turning off, and the second path may contribute to pulling down and/or maintaining the output signal V_{OUT} at its low level due to the second NMOS transistor MN4 turning on.

At time t₇, the delayed output signal V_{CNT} may begin its falling transition in accordance with the delay set by the delay circuit 608. At time t₈, the delayed output signal V_{CNT} may decrease past its threshold level V_{TH}, which may turn off the third NMOS transistor MN5. With the third NMOS transistor MN5 turning off, the output node B may be floating with reference to the first path. However, since the second NMOS transistor MN4 is still turned on, then the second path may operate to maintain the output signal V_{OUT} at its low level. The delay of the delay circuit 608 may be set such that the delayed output signal V_{CNT} does not turn off the third NMOS transistor MN5 until after the second NMOS transistor MN4 turns on at time t₆. In this way, the pull-down circuit 604 may remain in the pull-down mode when the third NMOS transistor MN5 turns off. In contrast, if the delay of the delay circuit 608 is set such that the third NMOS transistor MN5 turns off before the second NMOS transistor MN4 turns on, then there would be a period of time from when the third NMOS transistor MN5 turns off to when the second NMOS transistor MN4 turns on in which the pull-down circuit 604 is configured in the floating mode, and thus unable to keep down the output signal V_{OUT} at its low level.

The inverted first complimentary signal V_{AN}, the second complimentary signal V_{AB}, the output signal V_{OUT,} and the delayed output signal V_{CNT} may remain at their respective levels until a next cycle, when the first input signal V_{AB} performs a next earlier falling transition at a time t₉.

In view of the operation of the example circuit configuration 600 as described with reference to FIG. 7, the third NMOS transistor MN5 may be added to the pull-down circuit 604 to reduce contention between the pull-up and pull-down circuits 602, 604 during those parts of the cycle when one of the signals V_{AB}, V_{AN} performs its transition, but the other has not. However, because the addition of the third NMOS transistor MN5 may cause the output node B to float relative to the first path prior to a next cycle, the second PMOS transistor MP8 and the second NMOS transistor MN4 of the second path function as a control latch to maintain the output signal V_{OUT} at its low level until the second complimentary signal V_{AB} performs its next falling transition at time t₉.

Additionally, the delay circuit 608 may be set with a sufficient delay such that there is no contention in the first path when the second complimentary signal V_{AB} performs its earlier falling transition, and such that the output node B does not float relative to the first path until after the second path is maintaining the output signal V_{OUT} at node B at its low level. From a design perspective, the delay circuit 608 may be designed to have a delay that is greater than a maximum of the difference between the fall time of the second complimentary signal V_{AB} and the fall time of the inverted first complimentary signal V_{AN}, and the difference between the rise time of the second complimentary signal V_{AB} and the rise time of the inverted first complimentary signal V_{AB}.

Also, as previously described, the first and second PMOS transistors MP7, MP8 and the first and second NMOS transistors MN3, MN4 forming the first and second paths may be referred to as a “mixer” circuit in the sense that transistors MP7, MP8, MN3, MN4 are configured to “mix” the earlier falling transitions of the first and second complimentary signals V_{A}, V_{AB} output from the level shifter 102 to generate the output signal V_{OUT}. For the example circuit configuration 600, the third NMOS transistor MN3 and the delay circuit 608 may be referred to as “transition sense circuitry” in the sense that the “transition sense circuitry” may be configured to “sense” the transitions to remove or at least reduce contention between the pull-up and pull-down circuits 602, 604

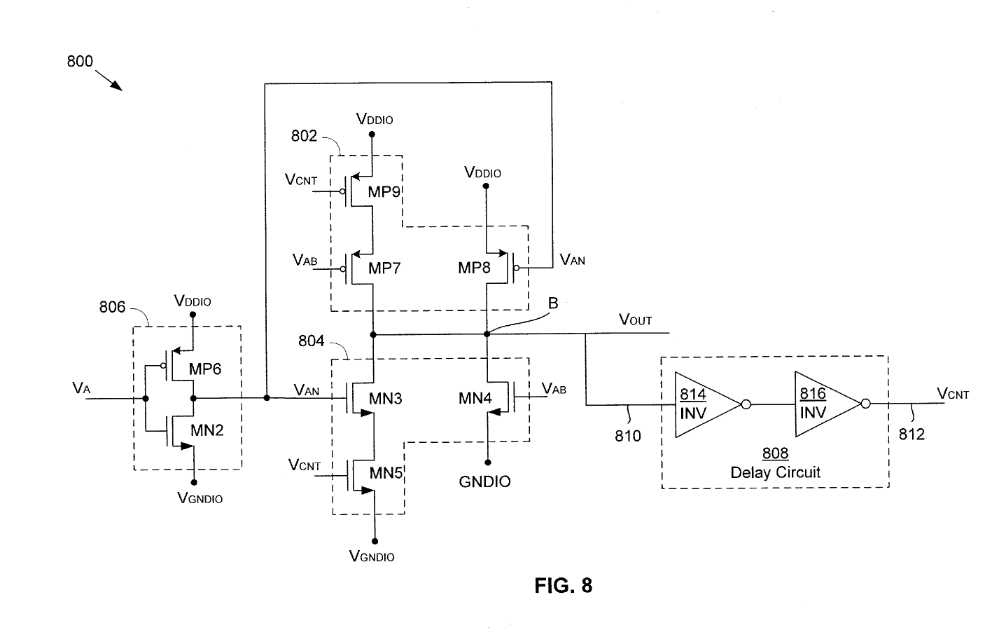

FIG. 8 shows a third example circuit configuration 800 of the transition tracking circuit 106. Like the example circuit configurations 400 and 600, the example circuit configuration 800 may include a pull-up circuit 802, a pull-down circuit 804, an inverter circuit 806, and a delay circuit 808. The pull-down circuit 804 may have the same configuration as the pull-down circuit 604 in that it has the second NMOS transistor MN4 connected in parallel with the series connection of the first and third NMOS transistor MN3 and MN5. In addition, the inverter circuit 806 may have the same configuration of PMOS and NMOS transistors MP6, MN2 as the inverter circuit 606, and the delay circuit 808 may have the same chain of inverters 814, 816 as the delay circuit 608.

The pull-up circuit 802 may differ from the pull-up circuit 602 in that the pull-up circuit 802 may include a third PMOS transistor MP9 connected in series with the first PMOS transistor MP7. In particular, a source terminal of the third PMOS transistor MP9 may be connected to the source voltage V_{DDIO} and a drain terminal of the third PMOS transistor MP9 may be connected to the source terminal of the first PMOS transistor MP7. In addition, a gate terminal of the third PMOS transistor may be connected to the output of the delay circuit 806 and configured to receive the delayed output signal V_{CNT}.

Accordingly, a first path of series connected transistors for the example circuit configuration 800 may include the third PMOS transistor MP9, the first PMOS transistor MP7, the first NMOS transistor MN3, and the second NMOS transistor MN5. A second path for the example circuit configuration 600 may be the same as the second path for the example circuit configuration 600, and include the second PMOS transistor MP8 and the second NMOS transistor MN4.

Referring back to timing diagram of FIG. 7, the example circuit configuration 800 may operate similarly to the example circuit configuration 600, except that at time t₄ when the delayed output signal V_{CNT} increases to its threshold level V_{TH}, the third PMOS transistor MP9 may turn off, which in turn may cause the output node B to float relative to the first path of transistors MP9, MP8, MN3, MN5. Further, at time t₅ when the inverted complimentary signal V_{AN} performs the earlier rising transition and the first NMOS transistor MN3 turns on, the third PMOS transistor MP9 being turned off may remove the contention in the first path due to the first PMOS transistor MP7 being turned on. Accordingly, by including the third PMOS transistor MP9 in the first path and configured it to receive the delayed output signal V_{CNT}, contention may be eliminated for both the earlier falling transition of the second complimentary signal V_{AB} at time t₁, and the earlier falling transition of the first complimentary signal V_{A} (and the earlier rising transition of the inverted first complimentary signal V_{AN}) at time t₅.

Referring back to FIG. 8, the third PMOS transistor MP9 may be considered part of the “transition sense circuitry” that “senses” the transitions to remove or at least reduce contention between the pull-up and pull-down circuits 802, 804.

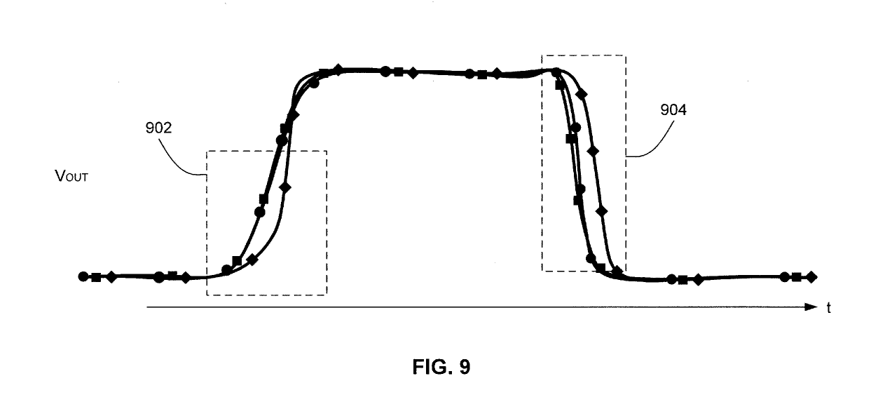

FIG. 9 shows a timing diagram of example waveforms as a function of time t of the output signal V_{OUT} as generated by the different example circuit configurations 400, 600, and 800. The waveform of the output signal V_{OUT} generated by example circuit configuration 400 may be represented by the curve with the diamonds, the waveform of the output signal V_{OUT} generated by the example circuit configuration 600 may be represented by the curve with the circles, and the waveform of the output signal V_{OUT} generated by the example circuit configuration 800 may be represented by the curve with the squares.

As highlighted by the dotted box 902, in response to the second complimentary signal V_{AB} performing the earlier falling transition, the output signal V_{OUT} generated by the first example configuration 400 may rise later and/or not as quickly as the output signal V_{OUT} generated by the second and third example configurations 600, 800, particularly during the beginning of the rising transition and around the time of the 50% swing, due to contention, which may be absent or reduced during operation of the second and third example configurations 600, 800. In addition, as highlighted by the dotted box 904, the output signal V_{OUT} generated by the second and third example configurations 600, 800 may fall more quickly and/or sooner than the output signal V_{OUT} generated by the first example configuration 400 due to the reduction in contention when the second input signal performs the earlier rising transition. Further, particularly during the beginning half of the falling transition, the output signal V_{OUT} generated by the third example circuit configuration 800 may fall slightly sooner and/or more quickly than the output signal V_{OUT} generated by the second example circuit configuration 600, due to the removal of the contention in the first path when the second input signal V_{AN} performs a rising transition before the second complimentary signal V_{AB}.

Referring to any of the example circuit configurations 400, 600, 800, the pull-up and/or pull-down circuits may have circuit configurations other than those shown and described with reference to FIGS. 4, 6, and 8. For example, additional NMOS and/or PMOS transistors may be included. In addition or alternatively, switches or switching circuitry other than NMOS and PMOS transistors may be used, such as a PNP bipolar junction transistor as an example.

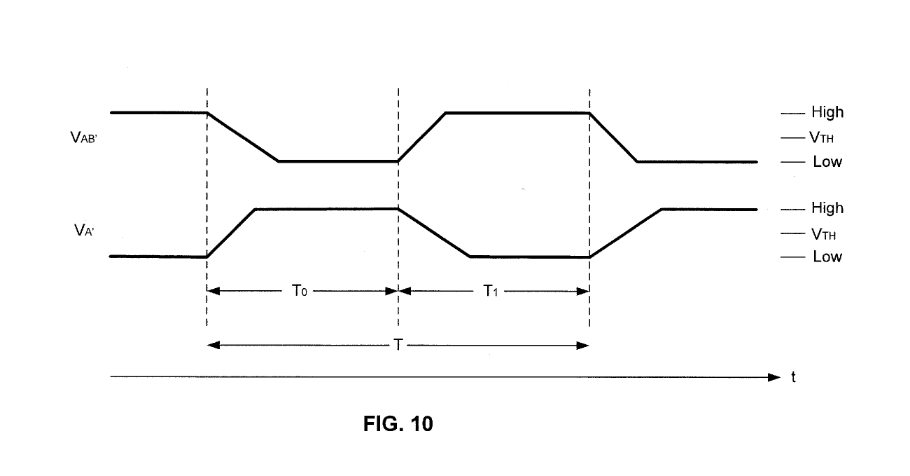

In addition, the example circuit configurations 400, 600 and 800 are for when the first and second complimentary signal V_{A}, V_{AB} perform their falling transitions faster and/or earlier than they perform their rising transitions. The transition tracking circuit 106, including the circuit configurations 400, 600, 800, may be implemented with and appropriately modified to receive and respond to a pair of complimentary signals V_{A′}, V_{AB′} having faster and/or earlier rising transitions. FIG. 10 shows a timing diagram of such complimentary signals V_{A′}, V_{AB}. As shown in FIG. 10, during a first portion Tₒ of a time period T, the first complimentary signal V_{A′} may perform a rising transition earlier and/or faster than the second complimentary signal V_{AB′} may perform a falling transition. Similarly, during a second portion T₁ of the time period T, the second complimentary signal V_{AB′} may perform a rising transition faster and/or earlier than the first complimentary signal V_{A′} may perform a falling transition.

For these complimentary signals V_{A′}, V_{AB′}, the circuit configurations 400, 600, 800 shown in FIGS. 4, 6, 8 may be modified to generate an output signal V_{OUT} that tracks the earlier rising transitions. In particular, the connections for the PMOS transistors MP7, MP8 and the NMOS transistors MN3, MN4 may be switched.

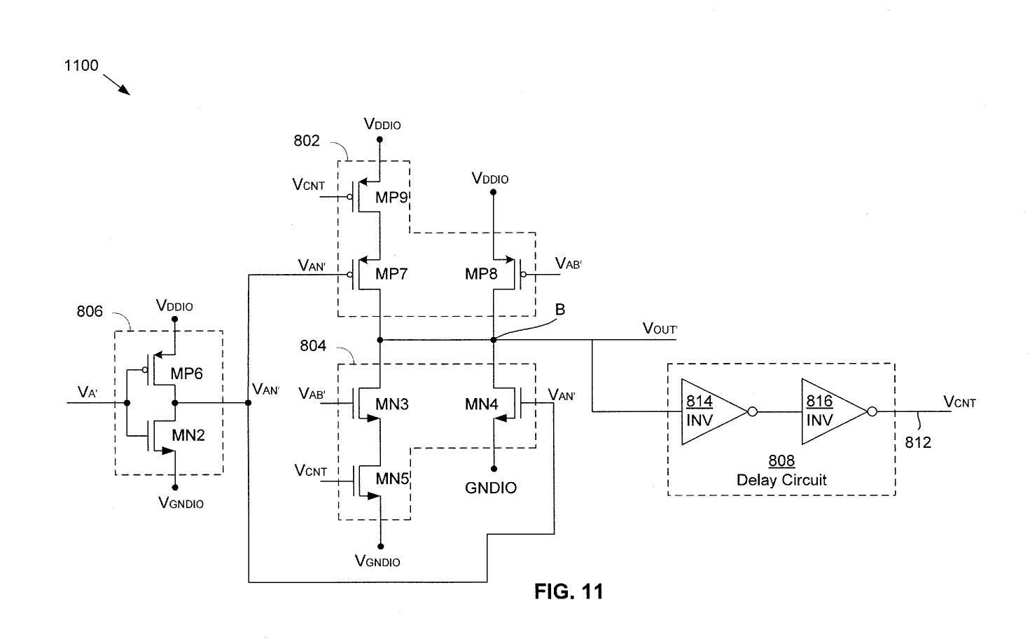

FIG. 11 shows a circuit schematic of an example circuit configuration 1100 that may be used to generate an output signal Vₒᵤᵣ based on the complimentary signals V_{A′}, V_{AB′} that perform earlier rising transitions. The circuit configuration 1100 shown in FIG. 11 is a modified version of the circuit configuration 800 shown in FIG. 8. In particular, the example circuit configuration 1100 may include the pull-up circuit 802, the pull-down circuit 804, the inverter circuit 806, and the delay circuit 808 of the circuit configuration 800. In addition, the first input signal V_{A′} may be input to the inverter circuit 806 to generate an inverted first input signal V_{AN′}. However, for the circuit configuration 1100, the inverted first complimentary signal V_{AN′} may be sent to the first PMOS transistor MP7 and the second NMOS transistor MN4, and the second complimentary signal V_{AB′} may be sent to the second PMOS transistor MP8 and the first NMOS transistor MN3. Similar modifications may be made to the example circuit configurations 400 and 600 shown in FIGS. 4 and 6, respectively.

Accordingly, whether the signals perform earlier/faster falling transitions or earlier/faster rising transitions, the transition tracking circuit 106 may configured to generate an output signal that tracks or begins transitioning its level in response to the earlier transition and irrespective of the later transition of a pair of complimentary signals V_{A} and V_{AB}

In still other applications, the transition tracking circuitry 106 may be modified for use with signals that are generally in phase with each other rather than complimentary. That is, despite being in phase, during a first portion of a cycle, a first signal performs its first (rising or falling) transition faster and/or earlier than a second signal performs its first (rising or falling) transition, and during a second portion of the cycle, the second signal performs its second (rising or falling) transition faster and/or earlier than the first signal performs its second (rising or falling) transition. For these other situations, the inverter circuit may be removed from the transition and tracking circuitry.

Further, the transition tracking circuitry 106, may be used and/or implemented with circuitry other than level shifters. In general, the transition tracking circuit 106 may be used for any application where two signals having either a faster rising or a falling transition may be generated, and where generation and use of an output signal that tracks the faster transitions of each of the signals may be more desirable than use of either or both of the original two signals.

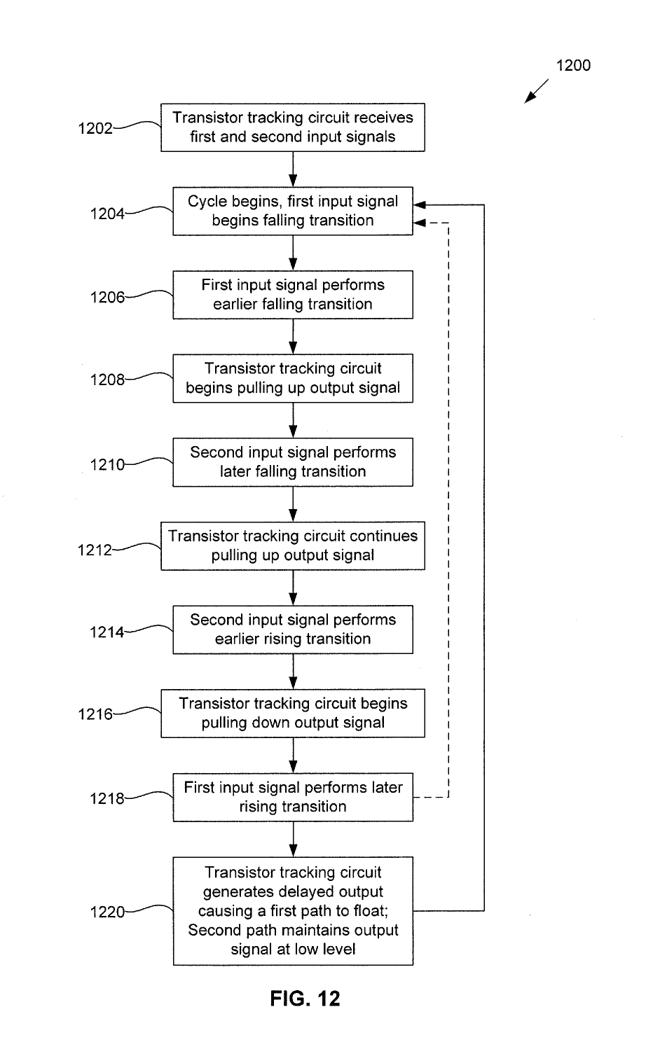

FIG. 12 is a flow chart of an example method 1200 of generating an output signal that transitions between a high level and a low level. At block 1202 a transition tracking circuit may receive a pair of input signals, including a first input signal and a second input signal. Each of the first input signal and the second input signal may be at respective high levels. In response to the first and second input signals being at high levels, a pull-up circuit of the transition tracking circuit may be in a floating mode, while a pull-down circuit of the transition tracking circuit may be in a pull-down mode, pulling down and maintaining the output signal at its low level.

At block 1204, a cycle during which time each of the first and second input signals may perform a rising transition and a falling transition. At the beginning of the cycle, the first input signal being received by the transition tracking circuit may begin a falling transition. At block 1206, the first input signal may perform its falling transition by reaching a threshold level and the second input signal may not yet have performed a falling transition (e.g., the second input signal is still at its high level or a level above its threshold level).

At block 1208, in response to the earlier falling transition of the first input signal, the pull-up circuit may change from the floating mode to a pull-up mode to pull up the level of the output signal. For some example methods, at block 1208, the pull-down circuit may remain in the pull-down mode and the level of the output signal may begin rising due to contention between the pull-up circuit and the pull-down circuit. For other example methods, the pull-down circuit may switch to a floating mode, and so the pull-up circuit may pull up the level of the output signal without contention.

At block 1210, the second input signal may perform its later falling transition. At block 1212, in response to the later falling transition, the pull-down circuit may change to a floating mode if it was not already configured in the floating mode, which in turn may remove any contention between the pull-up and pull-down circuits. Accordingly, at block 1212, the pull-up circuit may continue pulling up and/or maintaining the output signal at its high level.

At block 1214, the second input signal may perform a rising transition and the first input signal may not yet have performed a rising transition (e.g., the first input signal is still at its low level or a level below its threshold level). At block 1216, in response to the earlier rising transition of the second input signal, the pull-up and pull-down circuits may begin decreasing the level of the output signal. For some example methods, the level of the output signal may begin decreasing due to contention between the pull-up circuit and the pull-down circuit. In addition, for some example methods where there is contention, the pull-circuit may use more transistors and/or generate a larger current draw to reduce the contention when pulling down the level of the output signal, although for other example methods, the same number of transistors may be used when pulling down the level with contention. In still other example methods, when the second input signal performs its earlier rising transition, the pull-up circuit may be configured in the floating mode, allowing the pull-down circuit to pull down the level of the output signal without contention. The pull-up circuit may be configured in the floating mode by generating a delayed output signal and sending the delayed output signal to the pull-up circuit. The delay may be such that after the second input signal performs its later falling transition, the delayed output signal increases to a level that configures the pull-up circuit in the floating mode. As such, when the pull-down circuit changes from the floating mode to the pull down mode in response to the second input signal performing its earlier rising transition, there is no contention between the pull-up and pull-down circuits.

At block 1218, the first input signal may perform its later rising transition. In response, the pull-up circuit may change to being in the floating mode if it was not already while the pull-down circuit remains in the pull-down mode, which may allow the pull-down circuit to continue pulling down and/or maintaining the output signal at its low level.

For some example methods, the method may proceed back to block 1204 where a next cycle may begin, as denoted by the dotted arrow. For other example methods, the method may proceed to block 1220, where the transition tracking circuit generates a delayed output signal at a level that causes an output node at which the output signal is generated to float relative to a first path of transistors. For these example methods where a delayed output signal is generated, the method may include maintaining the output signal generated at the output node at its low level with a second path of transistors while the output node is floating relative to the first path. The method may then proceed back to block 904, where a next cycle may begin.

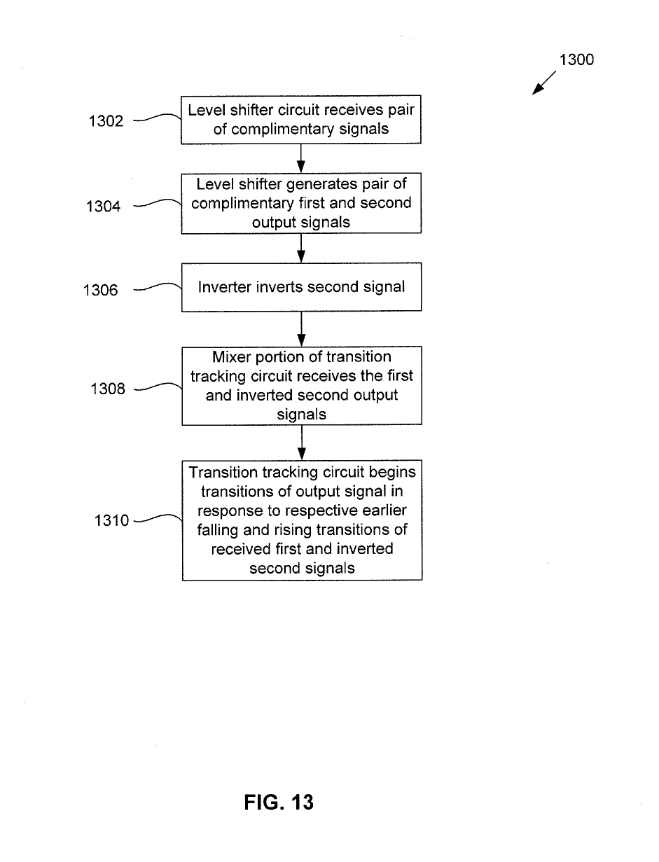

FIG. 13 is a flow chart of an example method 1300 of generating a level-shifted output signal. At block 1302, a pair of complimentary input signals transitioning between high and low levels in a first domain may be received by a level shifter circuit. The pair of complimentary input signals may have an associated duty cycle. At block 1304, the level shifter circuit may generate a pair of complimentary output signals, including a first output signal and a second output signal. The first and second output signals may generally track each other in that during a first portion of a cycle, the first output signal may perform a falling transition and the second output signal may perform a rising transition, and during a second portion of the cycle, the first output signal may perform a rising transition and the second output signal may perform a falling transition. The first and second output signals may each perform falling transitions earlier than the other's rising transition, or alternatively may each perform rising transitions faster than the other's falling transition.

At block 1306, an inverter circuit of a transition tracking circuit may invert the second output signal such that during a first portion of a cycle, the first output signal may perform its falling transition before the inverted second output signal performs its falling transition, and during a second portion of the cycle, the inverted second output signal may perform its rising transition before the first output signal performs its rising transition.

At block 1308, a mixer portion of the transition tracking circuit may receive the first and inverted second output signals as input signals. At block 1310, the transition tracking circuit may respond to the first and inverted second input signals by generating an output signal at an output node such that the transition tracking circuit may begin to increase the level of the output signal toward its high level in response to the first input signal performing the earlier falling transition and irrespective of the inverted second input signal performing the later falling transition, and may begin to decrease the level of the output signal toward its low level in response to the inverted second input signal performing the earlier rising transition and irrespective of the inverted second input signal performing the later rising transition. The resulting output signal generated by the transition tracking circuit may have a duty cycle closer to the duty cycle associated with the complimentary input signals input to the level shifter circuit, than the duty cycle of either of the output signals generated by the level shifter circuit.

It is intended that the foregoing detailed description be understood as an illustration of selected forms that the embodiments can take and does not intend to limit the claims that follow. Also, some of the following claims may state that a component is operative to perform a certain function or configured for a certain task. It should be noted that these are not restrictive limitations. It should also be noted that the acts recited in the claims can be performed in any order—not necessarily in the order in which they are recited. Additionally, any aspect of any of the preferred embodiments described herein can be used alone or in combination with one another. In sum, although the present invention has been described in considerable detail with reference to certain embodiments thereof, other versions are possible. Therefore, the spirit and scope of the appended claims should not be limited to the description of the embodiments contained herein.

We claim:

1. A transition tracking circuit comprising:
a node at which an output signal is generated; and
pull-up and pull-down circuitry coupled to the node, the pull-up and pull-down circuitry configured to:
receive a first input signal and a second input signal, wherein during each of a plurality of time periods, the first input signal and the second input signal each perform a first transition and a second transition, the first transition performed by the first input signal occurring earlier than the first transition performed by the second input signal and the second transition performed by the second input signal occurring earlier than the second transition performed by the first input signal;
begin pulling up an amplitude of the output signal generated at the node from a low level in response to the earlier first transition performed by the first input signal; and
begin pulling down the amplitude of the output signal generated at the node from a high level in response to the earlier second transition performed by the second input signal.

2. The transition tracking circuit of claim 1, wherein the pull-up and pull-down circuitry is configured to at least one of: begin pulling up or begin pulling down the amplitude of the output signal without contention between a pull-up circuit portion and a pull-down circuit portion of the pull-up and pull-down circuitry.

3. The transition tracking circuit of claim 1, wherein the pull-up and pull-down circuitry comprises a pull-up circuit portion and a pull-down circuit portion, and wherein the pull-up circuit portion and the pull-down circuit portion are each configured to receive both the first input signal and the second input signal.

4. The transition tracking circuit of claim 3, wherein the pull-up circuit portion comprises a first p-type metal-oxide-semiconductor (PMOS) transistor and a second PMOS transistor each having a drain terminal coupled to the output node, and wherein the pull-down circuit portion comprises a first n-type metal-oxide-semiconductor (NMOS) transistor and a second NMOS transistor each having a drain terminal coupled to the output node.

5. The transition tracking circuit of claim 1, wherein the pull-up and pull-down circuitry comprises:
a first path of first transistors coupled to the node and configured to pull up and pull down the amplitude of the output signal at the node;
a second path of second transistors coupled to the node and configured to pull up and pull down the amplitude of the output signal at the node; and
a delay circuit configured to:
receive the output signal; and
output, to the first path, a delayed output signal that transitions from a first level that prevents the first path from pulling down the amplitude of the output signal to a second level that allows the first path to pull down the amplitude of the output signal after the first transition of the second input signal occurs.

6. The transition tracking circuit of claim 5, wherein the delayed output signal output from the delay circuit further transitions from the second level to the first level after the second transition of the first input signal occurs.

7. The transition tracking circuit of claim 6, wherein the delay circuit is configured to output the delayed output signal to a n-type metal-oxide-semiconductor (NMOS) transistor of the first path.

8. The transition tracking circuit of claim 7, wherein the delay circuit is further configured to output the delayed output signal to a p-type metal-oxide-semiconductor (PMOS) transistor of the first path, wherein the delayed output signal at the first level further allows the first path to pull up the amplitude of the output signal, and wherein the delayed output signal at the second level further prevents the first path from pulling up the amplitude of the output signal.

9. The transition tracking circuit of claim 6, wherein the second path of second the transistors is configured to maintain the output signal at the low level when the delayed output signal transitions from the second level to the first level.

10. The transition tracking circuit of claim 1, further comprising an inverter circuit configured to:
receive a third input signal;
invert the third input signal to generate the second input signal; and
output the second input signal to the pull-up and pull-down circuitry.

11. The transition tracking circuit of claim 1, wherein in response to the earlier second transition performed by the second input signal, the pull-up and pull-down circuitry is configured to have turned on at least one first transistor to pull up the amplitude of the output signal and to have turned on a plurality of second transistors to pull down the amplitude of the output signal, wherein a first number of the at least one first transistor is less than a second number of the plurality of second transistors.

12. The transition tracking circuit of claim 1, wherein the first transitions performed by each of the first and second input signals comprises falling transitions, and wherein the second transitions performed by each of the first and second input signals comprises rising transitions.

13. A method of generating an output signal, the method comprising:
receiving, with a transition tracking circuit, a pair of complimentary input signals comprising a first signal and a second signal, wherein during a first time period portion of each of a plurality of time periods, the first input signal performs a first falling transition earlier than the second input signal performs a first rising transition, and wherein during a second time period portion of each of the plurality of time periods, the second input signal performs a second falling transition earlier than first input signal performs a second rising transition; and
generating, at a node of the transition tracking circuit, the output signal having an amplitude that transitions between a high level and a low level,
wherein generating the output signal at the node comprises initiating the transitions of the amplitude of the output signal between the high level and the low level in response to the earlier first falling transition of the first input signal and the earlier second falling transition of the second input signal.

14. The method of claim 13, wherein generating the output signal at the node further comprises:
beginning to pull up, with a pull-up circuit coupled to the node, the amplitude of the output signal generated at the node from the low level in response to the earlier first falling transition of the first input signal; and
beginning to pull down, with a pull-down circuit coupled to the node, the amplitude of the output signal generated at the node from the high level in response to the earlier second falling transition of the second input signal.

15. The method of claim 14, wherein beginning to pull up the amplitude of the output signal comprises beginning to pull up, with the pull-up circuit, the amplitude of the output signal in response to the earlier first falling transition without contention between the pull-up circuit and the pull-down circuit.

16. The method of claim 14, wherein beginning to pull down the amplitude of the output signal comprises beginning to pull down, with the pull-down circuit, the amplitude of the output signal in response to the earlier second falling transition without contention between the pull-up circuit and the pull-down circuit.

17. The method of claim 13, wherein the transition tracking circuit further comprises a first path of first transistors coupled to the node, and a second path of second transistors coupled to the node, and wherein generating the output signal at the node further comprises transitioning the amplitude of the output signal between the high level and the low level with at least one of the first path or the second path.

18. The method of claim 17, further comprising:
receiving, with a delay circuit, the output signal;
in response to receiving the output signal, generating, with the delay circuit, a delayed output signal; and
receiving, with the first path, the delayed output signal from the delay circuit such that the delayed output signal:
transitions from a first level that prevents the first path from pulling down the amplitude of the output signal to a second level that allows the first path to pull down the amplitude of the output signal after the first rising transition of the second input signal; and
transitions from the second level to the first level after the second rising transition of the first input signal.

19. The method of claim 18, wherein the first level of the delayed output signal further allows the first path to pull up the amplitude of the output signal, and wherein the second level of the delayed output signal further prevents the first path from pulling up the amplitude of the output signal.

20. The method of claim 18, further comprising:
maintaining, with the second path of second transistors, the output signal at the low level when the delayed output signal transitions from the second level to the first level.

21. A level shifter system comprising:
a level shifter circuit configured to generate a pair of complimentary signals in a second domain based on an input signal in a first domain, wherein during each of a plurality of time periods, a first signal of the pair performs a first falling transition earlier than a second signal of the pair performs a first rising transition, and the second signal performs a second falling transition earlier than the first signal performs a second rising transition; and
a transition tracking circuit configured to generate an output signal having an amplitude that transitions between a high level and a low level, wherein the transition tracking circuit is configured to generate the output signal such that the transitions of the output signal track the earlier first falling transition performed by the first input signal and the earlier second falling transition performed by the second input signal.

22. The level shifter system of claim 21, further comprising an inverter circuit,
wherein the level shifter circuit is further configured to:
send one of the first signal and the second signal to the inverter circuit before the one of the first signal and the second signal is sent to the transition tracking circuit; and send the other of the first signal and the second signal to the transition tracking circuit without being inverted with the inverter circuit.
